(19) United States
(12) Patent Application Publication
(10) Pub. No.: US 2026/0218003 A1
(43) Pub. Date: Jul. 30, 2026

(54) RESIN COMPOSITION FOR ENCAPSULATING ELECTRONIC DEVICE AND ELECTRONIC DEVICE MANUFACTURED USING SAME

(71) Applicant: DONGWOO FINE-CHEM CO., LTD., Jeollabuk-do (KR)

(72) Inventors: YU MI AHN, Jeollabuk-do (KR); JEONG MIN KANG, Jeollabuk-do (KR); SU SEONG KIM, Jeollabuk-do (KR); SEONG HWAN PARK, Jeollabuk-do (KR); DONG CHAN LEE, Jeollabuk-do (KR)

(21) Appl. No.: 19/146,646

(22) PCT Filed: Jan. 9, 2024
(86) PCT No.: PCT/KR2024/000406

§ 371 Date: Jul. 9, 2025

(30) Foreign Application Priority Data
Jan. 12, 2023 (KR) 10-2023-0004491

(51) Int. Cl. C09D 163/00; C08G 59/24; C08G 59/32; C08G 59/38; C08G 59/62; C08K 3/22; C08K 5/5425; C08K 5/5435; C08K 5/544; C08K 9/06; C09D 7/62; C09D 7/63; H10W 74/10; H10W 74/47

(52) U.S. Cl. CPC C09D 163/00; C08G 59/245; C08G 59/3218; C08G 59/38; C08G 59/621; C09D 7/62; C09D 7/63; H10W 74/137; H10W 74/473; C08K 2003/2227; C08K 5/5425; C08K 5/5435; C08K 5/544; C08K 9/06

(57) ABSTRACT

A resin composition for encapsulating an electronic device includes an epoxy-base compound containing a biphenyl-based epoxy compound, and an inorganic filler comprising first alumina particles surface-treated with a silane agent including an alkyl group of a carbon number of 7 or higher, and second alumina particles that have been not treated with silane. The amount of first alumina particles is 4-35 wt % on the basis of the total weight of the composition.

### BACKGROUND

### 1. Technical Field

The present invention relates to a resin composition for sealing an electronic device and an electronic device manufactured using the same. More particularly, the present invention relates to a resin composition for sealing an electronic device including an epoxy-based resin and an additive, and an electronic device manufactured using the same.

### 2. Background Art

An integrated circuit (IC) chip including a semiconductor device is surface-mounted on a circuit board by, e.g., a bump, a solder or a ball grid array (BGA). The semiconductor device may be sealed or packaged using an epoxy molding compound (EMC)-based resin on the circuit board.

Recently, as a degree of integration of the semiconductor device increases and a size decreases, an application of a sealing resin composition having improved moldability and curing properties is needed.

For example, the IC chip may be mounted on a BGA substrate, and then the EMC composition may be used to fill a gap between the IC chip and the BGA substrate to fix the IC chip.

As the gap decreases, an EMC composition having a sufficient flow length is required. Additionally, a heat dissipation property capable of sufficiently dissipating a heat generated during an operation of a semiconductor device to an outside may be required in the EMC composition.

Further, thermal stability is required from the EMC composition to provide sufficient resistance to the heat generated from the semiconductor device and stable chip fixing properties.

For example, Korean Patent Publication No. 10-2340610 discloses an epoxy molding resin composition containing inorganic fillers, but the composition may not provide sufficient moldability and thermal properties suitable for a high-integration semiconductor package.

### SUMMARY

An object of the present invention is to provide a resin composition for sealing an electronic device having improved mechanical properties and thermal stability.

An objective of the present invention is to provide an electronic device fabricated by using the resin composition for sealing an electronic device.

1. A resin composition for sealing an electronic device, including: an epoxy-based compound including a biphenyl-based epoxy compound; and an inorganic filler including first alumina particles surface-treated with a silane agent that includes an alkyl group having 7 or more carbon atoms, and second alumina particles that are not silane-treated, wherein a content of the first alumina particles is in a range from 2.5 wt % to 35 wt % based on a total weight of the composition.

2. The resin composition for sealing an electronic device according to the above 1, wherein the first alumina particles are surface-treated with a silane agent that includes an alkyl group having 7 to 11 carbon atoms, and a content of the first alumina particles is in a range from 2.5 wt % to 35 wt % based on the total weight of the composition.

3. The resin composition for sealing an electronic device according to the above 1, wherein the first alumina particles are surface-treated with a silane agent that includes an alkyl group having 12 to 15 carbon atoms, and a content of the first alumina particles is in a range from 2.5 wt % to 26 wt % based on the total weight of the composition.

4. The resin composition for sealing an electronic device according to the above 1, wherein the first alumina particles are surface-treated with a silane agent that includes an alkyl group having 16 to 20 carbon atoms, and a content of the first alumina particles is in a range from 2.5 wt % to 17 wt % based on the total weight of the composition.

5. The resin composition for sealing an electronic device according to the above 1, wherein an amount of the second alumina particles is greater than an amount of the first alumina particles.

6. The resin composition for sealing an electronic device according to the above 1, wherein a content of the inorganic filler is in a range from 85 wt % to 95 wt % based on the total weight of the composition

7. The resin composition for sealing an electronic device according to the above 1, wherein a content of the biphenyl-based epoxy compound is in a range from 10 wt % to 80 wt % based on a total weight of the epoxy-based compound.

8. The resin composition for sealing an electronic device according to the above 7, wherein the epoxy-based compound further includes a biphenyl-aralkyl-based compound.

9. The resin composition for sealing an electronic device according to the above 8, wherein the biphenyl-based epoxy compound is a represented by Chemical Formula 1 below:

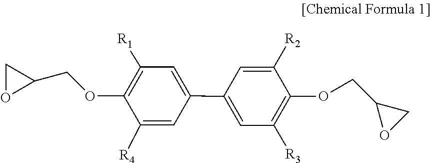

(In Chemical Formula 1, R₁, R₂, R₃ and R₄ are each independently hydrogen or an alkyl group having 1 to 5 carbon atoms)

10. The resin composition for sealing an electronic device according to the above 8, wherein the biphenyl-aralkyl-based epoxy compound is represented by Chemical Formula 2 below:

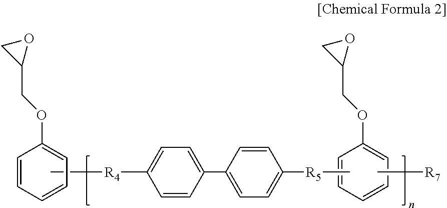

(In Chemical Formula 2, R₄ and R₅ are each an alkylene group having 1 to 5 carbon atoms, R₇ is hydrogen or an alkyl group having 1 to 5 carbon atoms, and n is an integer of 1 to 10).

11. The resin composition for sealing an electronic device according to the above 1, further including a curing agent including a phenol-based or a novolac-based resin, and a curing catalyst.

12. The resin composition for sealing an electronic device according to the above 11, wherein a content of the curing catalyst is in a range from 0.01 to 0.5 wt % based on the total weight of the composition.

13. The resin composition for sealing an electronic device according to the above 1, further including a silane coupling agent that includes an epoxy silane-based compound or an amino silane-based compound.

14. An electronic device including a sealant formed from the resin composition for sealing an electronic device according to the above described embodiments.

15. The electronic device according to the above 14, further including a circuit board and a semiconductor chip mounted on the circuit board, wherein the sealant fills a space between the circuit board and the semiconductor chip.

A resin composition for sealing an electronic device according to embodiments of the present invention may include alumina particles surface-treated with a silane agent as an inorganic filler. Accordingly, dispersibility of the inorganic filler in the composition may be increased to implement uniform heat dissipation properties and thermal conductivity. Further, flowability or a flow length of the composition may be improved by controlling the number of carbon atoms contained in the silane agent.

Thus, stable sealing may be formed in a micro-semiconductor package, and an amount of composition used for forming a sealing material may be reduced.

According to embodiments of the present invention, the flow length of the composition may be further increased by controlling a ratio of a biphenyl-based compound and a biphenyl-aralkyl-based compound included in an epoxy-based compound.

The resin composition for sealing an electronic device may be used as a sealing resin for a highly integrated semiconductor package to improve mounting reliability of a fine-sized integrated circuit chip.

### BRIEF DESCRIPTION OF THE DRAWING

FIGURE is a schematic cross-sectional view illustrating a semiconductor package using a resin composition for sealing an electronic device according to embodiments.

### DETAILED DESCRIPTION

According to embodiments of the present invention, a resin composition for sealing an electronic device including an epoxy-based compound and an inorganic filler is provided. Further, according to embodiments of the present invention, an electronic device using the resin composition for sealing an electronic device is provided.

### <Resin Composition for Sealing Electronic Device>

A resin composition for sealing an electronic device (hereinafter, abbreviated as a resin composition) according to embodiments may include an epoxy-based compound and an inorganic filler. The resin composition may further include a curing agent and a catalyst, and may further include an additive.

The term “resin composition” used in the present application is used to cover all cases in which a resin is directly included in the composition or the composition is cured to form a resin.

### Epoxy-Based Compound

The epoxy-based compound may be used to form a base resin or a binder resin that provides thermosetting properties of the resin composition. The epoxy-based compound may be crosslinked or cured to form an electronic device sealant including an epoxy-based resin.

The epoxy compound may include a biphenyl-based epoxy compound. The biphenyl-based epoxy compound may refer to a compound in which an epoxy group is bonded to both terminals of para positions of a biphenyl group via an ether group. For example, the biphenyl-based epoxy compound may be included to improve flow properties of the resin composition and enhance moldability.

In example embodiments, the biphenyl-based epoxy compound may be represented by Chemical Formula 1 below.

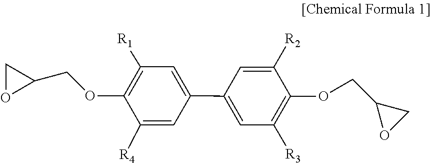

In Chemical Formula 1, R₁, R₂, R₃ and R₄ may each independently be hydrogen or an alkyl group having 1 to 5 carbon atoms.

In an embodiment, in Chemical Formula 1, R₁, R₂, R₃ and R₄ may each be a methyl group.

In example embodiments, the epoxy-based compound may further include a biphenyl-aralkyl-based epoxy compound. Mechanical properties of the sealant, such as hardness and elasticity, may be improved by the biphenyl-aralkyl-based epoxy compound.

The biphenyl-aralkyl-based epoxy compound may refer to an epoxy compound in which an alkylene group is bonded to each of two terminals at a para positions of a biphenyl group.

In example embodiments, the biphenyl-aralkyl-based epoxy compound may be represented by Chemical Formula 2 below.

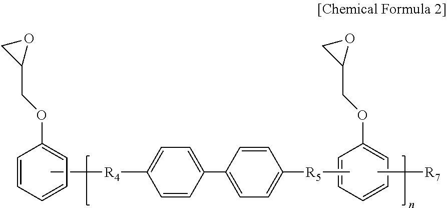

In Chemical Formula 2, R₄ and R₅ may each be an alkylene group having 1 to 5 carbon atoms, and R₇ may be hydrogen or an alkyl group having 1 to 5 carbon atoms. n is an integer ranging from 1 to 50, preferably from 1 to 30, from 1 to 20, or from 1 to 10.

In an embodiment, R₄ and R₅ may each be a methylene group (—CH₂—), and R₇ may be hydrogen.

In example embodiments, a content of the biphenyl-based epoxy compound may be in a range from 10 wt % to 80 wt % based on a total weight of the epoxy-based compound.

When the content of the biphenyl-based epoxy compound is less than 10 wt %, a sufficient flow length of the resin composition may not be provided. When the content of the biphenyl-based epoxy compound exceeds 80 wt %, hardness of the sealant formed using the resin composition may be lowered, and a glass transition temperature and thermal stability of the resin composition may be reduced.

Preferably, the content of the biphenyl-based epoxy compound may be in a range from 50 wt % to 80 wt %, more preferably from 60 wt % to 80 wt %.

The epoxy-based compound may be included in an amount from 1 to 10 wt %, preferably from 1 to 8 wt %, more preferably from 3 to 7 wt % based on a total weight of the resin composition (e.g., a solid content). In the above range, the resin composition may be sufficiently cured while maintaining appropriate flowability and molding properties.

In an embodiment, a bisphenol epoxy-based compound (e.g., a bisphenol F type resin) may not be included as the epoxy-based compound. In this case, an increase in flow length through the introduction of the biphenyl-based epoxy compound may be sufficiently and easily implemented.

### Inorganic Filler

The resin composition may include the inorganic filler. The heat dissipation properties in the semiconductor package may be effectively implemented using the sealant by the inorganic filler.

For example, the inorganic filler may include fused silica, crystalline silica, calcium carbonate, magnesium carbonate, alumina, magnesia, clay, talc, calcium silicate, titanium oxide, antimony oxide, glass fiber, etc. These may be used alone or in a combination of two or more therefrom.

Preferably, the inorganic filler may include alumina particles in consideration of heat dissipation properties.

According to embodiments of the present invention, the inorganic filler may include first alumina particles surface-treated with a silane agent, and second alumina particles that are not silane-treated.

The silane agent may stabilize the alumina particles by being chemically bonded or attached to surfaces of the first alumina particles to interact with the above-described epoxy-based compound or epoxy-based resin.

Thus, the inorganic filler may be uniformly dispersed in the resin composition or the sealant, thereby realizing uniform heat conduction properties in the semiconductor package. Therefore, sufficient heat dissipation properties and thermal conductivity may be achieved while relatively reducing an amount of the alumina particles.

Additionally, the silane agent may prevent agglomeration of the inorganic fillers, thereby increasing the flow length of the resin composition and enhancing moldability of the sealant.

The silane agent may include three alkoxy groups and one alkyl group directly bonded to a silicon atom. The alkoxy group may be a methoxy group.

In example embodiments, the carbon number of the alkyl group included in the silane agent may be 7 or more. In this case, the interaction with the siloxane-based resin may be effectively promoted.

Preferably, the carbon number of the alkyl group included in the silane agent may be 8 or more, more preferably 12 or more. In an embodiment, the carbon number of the alkyl group included in the silane agent may be 16 or more.

For example, if the carbon number of the alkyl group included in the silane agent is less than 7, the effect of increasing the flow length by the surface treatment may not be sufficiently implemented.

In an embodiment, the carbon number of the alkyl group included in the silane agent may be 20 or less in consideration of enhancement of thermal conductivity through the alumina particles.

According to embodiments of the present invention, a content of the first alumina particles may be in a range from 2.5 wt % to 35 wt %, preferably from 4 wt % to 35 wt % based on the total weight of the resin composition. When the content of the first alumina particles is less than 2.5 wt %, the flow length of the resin composition may be decreased and the heat dissipation properties may also be decreased. When the content of the first alumina particles exceeds 35 wt %, the thermal conductivity properties may be degraded by the alkyl groups of the silane agent.

In example embodiments, the content of the first alumina particles may be adjusted in consideration of the carbon number of the alkyl group included in the silane agent.

In an embodiment, when the carbon number of the alkyl group is in a range from 7 to 11, or from 8 to 11, the content of the first alumina particles may be adjusted in a range from 2.5 wt % to 35 wt %, preferably from 4 wt % to 35 wt %, more preferably from 9 wt % to 35 wt %.

In an embodiment, when the carbon number of the alkyl group is in a range from 12 to 15, the content of the first alumina particles may be adjusted in a range from 2.5 wt % to 26 wt %, preferably from 2.5 wt % to 20 wt %, or from 2.5 wt % to 18 wt %, more preferably from 4 wt % to 26 wt %, from 4 wt % to 20 wt %, or from 4 wt % to 18 wt %. In an embodiment, when the carbon number of the alkyl group is in a range from 16 to 20, the content of the first alumina particles may be adjusted in a range from 2.5 wt % to 17 wt %, preferably from 2.5 wt % to 10 wt %, more preferably from 4 wt % to 17 wt %, preferably from 4 wt % to 10 wt %.

The inorganic filler may be included in the largest amount of the resin composition to enhance the heat dissipation effect.

In example embodiments, an amount of the inorganic filler (e.g., a sum of the amount of the non-silane treated alumina particles and the amount of the alumina particles surface-treated with the silane agent) may be in a range from 85 wt % to 95 wt % based on the total weight of the resin composition.

For example, if the amount of the inorganic filler is less than 85 wt %, a thermal conductivity of the sealant may be decreased, and sufficient heat dissipation properties may not be provided. If the amount of the inorganic filler is greater than 95 wt %, a specific gravity or a weight of the sealant may be increased excessively and the flow length may be decreased.

Preferably, the amount of the inorganic filler may be in a range from 88 wt % to 95 wt %, or from 89 wt % to 92 wt %.

In some embodiments, an average particle diameter (D50) of the alumina particles may be in a range from 0.1 μm to 5 μm, preferably from 0.2 μm to 4 μm, or from 0.3 μm to 3 μm. In the particle diameter range, dispersibility and thermal conductivity of the alumina particles may be balanced.

As described above, the inorganic filler may include non-silane treated alumina particles together with the alumina particles surface-treated with the silane agent. An amount of the non-silane treated alumina particles (the second alumina particles) based on the total weight of the inorganic filler may be greater than an amount of the alumina particles surface-treated with the silane agent (the first alumina particles). In this case, the flow length may be effectively increased without degrading the thermal conductivity properties through the inorganic filler.

In some embodiments, the second alumina particles may be included as a remainder of the inorganic filler excluding the first alumina particles.

### Curing Agent

The resin composition may further include the curing agent. The curing agent may be crosslinked with the epoxy-based compound through an epoxy ring-opening reaction to improve a hardness of the sealant.

According to embodiments, the curing agent may include a resin including a hydroxyl group, and may include a phenol-based resin or a novolac-based resin.

For example, the curing agent may include a phenol novolac-type phenol resin, a polyfunctional phenol resin, a xylok-type phenol resin, a cresol novolac-type phenol resin, a naphthol-type phenol resin, a terpene-type phenol resin, a dicyclopentadiene-based phenol resin, a novolac-type phenol resin synthesized from bisphenol A and a resol, or the like. These may be used alone or in combination of two or more therefrom.

In an embodiment, the curing agent may include a repeating unit represented by Chemical Formula 3.

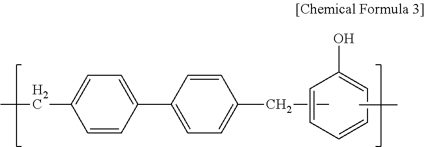

The curing agent may be included in an amount of 1 to 15 wt %, preferably 1 to 10 wt %, and more preferably 3 to 8 wt % based on the total weight of the resin composition. Within the above range, sufficient crosslinking properties with the epoxy-based compound may be achieved while maintaining appropriate flowability and molding properties.

### Curing Catalyst

The resin composition according to example embodiments may further include a curing catalyst that may promote the epoxy ring-opening reaction of the epoxy-based resin and the curing agent.

For example, the curing catalyst may include an amine-based compound, an organometallic compound, an organophosphorus compound, an imidazole-based compound, a boron compound, etc.

Non-limiting examples of the amine-based compound include benzyldimethylamine, triethanolamine, triethylenediamine, diethylaminoethanol, tri (dimethylaminomethyl) phenol, 2-2-(dimethylaminomethyl) phenol, 2,4,6-tris(diaminomethyl) phenol, tri-2-ethylhexyl acid salt, etc.

Non-limiting examples of the organometallic compound include chromium acetylacetonate, zinc acetylacetonate, nickel acetylacetonate, etc.

Non-limiting examples of the organophosphorus compound include tris-4-methoxyphosphine, tetrabutylphosphonium bromide, tetraphenylphosphonium bromide, phenylphosphine, diphenylphosphine, triphenylphosphine, triphenylphosphinetriphenylborane, triphenylphosphine-1,4-benzoquinone adduct, etc.

Non-limiting examples of the imidazole compound include 2-phenyl-4-methylimidazole, 2-methylimidazole, 2-phenylimidazole, 2-aminoimidazole, 2-methyl-1-vinylimidazole, 2-ethyl-4-methylimidazole, 2-heptadecylimidazole, etc.

Non-limiting examples of the boron compound include tetraphenylphosphonium-tetraphenylborate, triphenylphosphine tetraphenylborate, tetraphenylboron salt, trifluoroborane-n-hexylamine, trifluoroboranemonoethylamine, tetrafluoroboranetriethylamine, tetrafluoroboranamine, etc.

In some embodiments, the curing catalyst may be included in an amount from 0.01 to 0.5 wt %, preferably from 0.05 to 0.5 wt %, more preferably 0.06 to 0.5 wt % based on the total weight of the resin composition. Within the above range, a curing speed may be increased without decreasing the flow length. For example, when a content of the curing catalyst exceeds 0.5 wt %, the flow length may be excessively decreased.

### Additive

The resin composition may optionally include an additive in consideration of molding properties, adhesion properties, etc.

In an embodiment, the additive may include a coupling agent. For example, the coupling agent may improve interfacial compatibility between the resin component and the inorganic filler.

The coupling agent may include a silane coupling agent. For example, the coupling agent may include an epoxy silane-based compound, an amino silane-based compound, an alkyl silane-based compound, or the like, and the epoxy silane compound or the amino silane compound may be preferably used. In this case, the flow length of the resin composition may be additionally increased by the silane coupling agent.

In some embodiments, an acrylic silane compound containing an acrylate group or an acryloyl group may not be used as the silane coupling agent to prevent a reduction in the flow length.

In an embodiment, the additive may include a release agent. For example, molding separation may be promoted by the release agent. The release agent may include a silicone oil, a paraffinic wax, an ester wax, a fatty acid compound, or the like.

A content of the additive may be appropriately adjusted within a range that may not inhibit actions of the above-described epoxy-based compound, the curing agent, the curing catalyst and the inorganic filler.

For example, the content of the additive may be in a range from 0.01 wt % to 2 wt %, preferably 0.05 wt % to 1.5 wt %, more preferably 0.1 wt % to 1 wt % based on the total weight of the resin composition.

### <Electronic Devices>

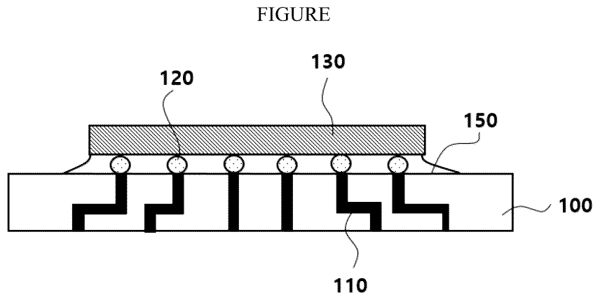

FIG. 1s a schematic cross-sectional view illustrating a semiconductor package using a resin composition for sealing an electronic device according to embodiments. For example, the electronic device may include the semiconductor package.

Referring to FIGURE, the electronic device may include a circuit board 100 and a semiconductor chip 130, and may include a sealant 150 for filling and bonding a space between the semiconductor chip 130 and the circuit board 100.

The circuit board 100 may include, e.g., a rigid printed circuit board (PCB), a main board, an interposer, etc. An internal wiring 110 may be included in the circuit board 100.

The semiconductor chip 130 may be mounted on the circuit board 100 by a surface mounting technology (SMT). The semiconductor chip 130 may include an AP chip, a logic device, a memory device, etc.

The semiconductor chip 130 may be electrically connected to the internal wiring of the circuit board 100 through a conductive intermediate structure 120. The conductive intermediate structure may include a solder, a bump, a ball grid array (BGA), etc.

The sealant 150 may be formed using the resin composition according to embodiments to fill a space between the semiconductor chip 130 and the circuit board 100, and may bond the semiconductor chip 130 and the circuit board 100 to each other. For example, the sealant may be formed by curing and molding the resin composition by an injection molding or a casting molding.

Hereinafter, experimental examples including specific examples and comparative examples are presented to enhance the understanding of the present invention, but this only exemplifies the present invention and does not limit the scope of the attached patent claims, and it is clear to those skilled in the art that various changes and modifications to embodiments can be made within the scope of the present invention and technical ideas, and it is obvious that these modifications and modifications are included in the range of to the attached patent claims.

### Examples and Comparative Examples

Resin compositions of Examples and Comparative Examples were prepared according to components and contents (parts by weight) shown in Tables 1 and 4 below.

TABLE 1

| | | Example | Example | Example | Example | Example | Example | Example |
|---|---|---|---|---|---|---|---|---|
| category | | 1 | 2 | 3 | 4 | 5 | 6 | 7 |
| epoxy- | biphenyl- | 3.200 | 3.200 | 3.200 | 3.200 | 3.200 | 3.200 | 3.200 |
| based | based | | | | | | | |
| compound | compound | | | | | | | |
| | (a) | | | | | | | |
| | biphenyl- | 1.372 | 1.372 | 1.372 | 1.372 | 1.372 | 1.372 | 1.372 |
| | aralkyl- | | | | | | | |
| | based | | | | | | | |
| | compound | | | | | | | |
| | (b) | | | | | | | |
| | bisphenol | — | — | — | — | — | — | — |
| | F type (c) | | | | | | | |
| curing agent | | 4.549 | 4.549 | 4.549 | 4.549 | 4.549 | 4.549 | 4.549 |
| curing catalyst | | 0.069 | 0.069 | 0.069 | 0.069 | 0.069 | 0.069 | 0.069 |
| coupling | amino | 0.270 | 0.270 | 0.270 | 0.270 | 0.270 | 0.270 | 0.270 |
| agent | silane- | | | | | | | |
| | based | | | | | | | |
| | epoxy | — | — | — | — | — | — | — |
| | silane- | | | | | | | |
| | based | | | | | | | |
| | acrylic | — | — | — | — | — | — | — |
| | silane- | | | | | | | |
| | based | | | | | | | |
| colorant | | 0.270 | 0.270 | 0.270 | 0.270 | 0.270 | 0.270 | 0.270 |
| release agent | | 0.270 | 0.270 | 0.270 | 0.270 | 0.270 | 0.270 | 0.270 |
| alumina | non-silane | 81 | 72 | 63 | 85.5 | 81 | 72 | 85.5 |
| | treated | | | | | | | |
| | C = 6 silane | — | — | — | — | — | — | — |
| | agent | | | | | | | |
| | surface- | | | | | | | |
| | treated | | | | | | | |
| | C = 8 silane | 9 | 18 | 27 | — | — | — | — |
| | agent | | | | | | | |
| | surface- | | | | | | | |
| | treated | | | | | | | |
| | C = 12 | — | — | — | 4.5 | 9 | 18 | — |
| | silane | | | | | | | |
| | agent | | | | | | | |
| | surface- | | | | | | | |
| | treated | | | | | | | |
| | C = 16 | — | — | — | — | — | — | 4.5 |
| | silane | | | | | | | |
| | agent | | | | | | | |
| | surface- | | | | | | | |
| | treated | | | | | | | |

TABLE 2

| | | Example | Example | Example | Example | Example | Example | Example |
|---|---|---|---|---|---|---|---|---|
| category | | 8 | 9 | 10 | 11 | 12 | 13 | 14 |
| epoxy- | biphenyl- | 3.200 | 3.200 | 1.476 | 3.594 | 3.200 | 0.506 | 3.800 |
| based | based | | | | | | | |
| compound | compound | | | | | | | |
| | (a) | | | | | | | |
| | biphenyl- | 1.372 | 1.372 | 3.445 | 0.898 | 1.372 | 4.62 | 0.754 |
| | aralkyl- | | | | | | | |
| | based | | | | | | | |
| | compound | | | | | | | |
| | (b) | | | | | | | |
| | bisphenol | — | — | — | — | — | — | — |
| | F type (c) | | | | | | | |
| curing agent | | 4.549 | 4.549 | 4.195 | 4.631 | 4.549 | 3.987 | 4.568 |
| curing catalyst | | 0.069 | 0.069 | 0.074 | 0.067 | 0.069 | 0.077 | 0.068 |
| coupling | amino | 0.270 | — | 0.270 | 0.270 | — | 0.27 | 0.27 |
| agent | silane- | | | | | | | |
| | based | | | | | | | |
| | epoxy | — | 0.270 | — | — | — | — | — |
| | silane- | | | | | | | |
| | based | | | | | | | |
| | acrylic | — | — | — | — | 0.270 | | |
| | silane- | | | | | | | |
| | based | | | | | | | |
| colorant | | 0.270 | 0.270 | 0.270 | 0.270 | 0.270 | 0.27 | 0.27 |
| release agent | | 0.270 | 0.270 | 0.270 | 0.270 | 0.270 | 0.27 | 0.27 |
| alumina | non-silane | 81 | 81 | 81 | 81 | 81 | 81 | 81 |
| | treated | | | | | | | |
| | C = 6 silane | — | — | — | — | — | — | — |
| | agent | | | | | | | |
| | surface- | | | | | | | |
| | treated | | | | | | | |
| | C = 8 silane | — | 9 | 9 | 9 | 9 | 9 | 9 |
| | agent | | | | | | | |
| | surface- | | | | | | | |
| | treated | | | | | | | |
| | C = 12 silane | — | — | — | — | — | — | — |
| | agent | | | | | | | |
| | surface- | | | | | | | |
| | treated | | | | | | | |
| | C = 16 silane | 9 | — | — | — | — | — | — |
| | agent | | | | | | | |
| | surface- | | | | | | | |
| | treated | | | | | | | |

TABLE 3

| | | Example | Example | Comparative | Comparative | Comparative |
|---|---|---|---|---|---|---|
| category | | 15 | 16 | Example 1 | Example 2 | Example 3 |
| epoxy- | biphenyl- | 3.200 | 3.200 | 3.200 | 3.200 | 3.200 |
| based | based | | | | | |
| compound | compound | | | | | |
| | (a) | | | | | |
| | biphenyl- | 1.372 | 1.372 | 1.372 | 1.372 | 1.372 |
| | aralkyl- | | | | | |
| | based | | | | | |
| | compound | | | | | |
| | (b) | | | | | |
| | bisphenol | — | — | — | — | — |
| | F type (c) | | | | | |
| curing agent | | 4.549 | 4.549 | 4.549 | 4.549 | 4.549 |
| curing catalyst | | 0.069 | 0.069 | 0.069 | 0.069 | 0.069 |
| coupling | amino | 0.270 | 0.270 | 0.270 | 0.270 | 0.270 |
| agent | silane- | | | | | |
| | based | | | | | |
| | epoxy | — | — | — | — | — |
| | silane- | | | | | |
| | based | | | | | |
| | acrylic | — | — | — | — | — |
| | silane- | | | | | |
| | based | | | | | |
| colorant | | 0.270 | 0.270 | 0.270 | 0.270 | 0.270 |
| release agent | | 0.270 | 0.270 | 0.270 | 0.270 | 0.270 |
| alumina | non-silane | 63 | 72 | 90 | 88 | 54 |
| | treated | | | | | |
| | C = 6 silane | — | — | — | | — |
| | agent | | | | | |
| | surface- | | | | | |
| | treated | | | | | |
| | C = 8 silane | — | — | — | 2 | 36 |
| | agent | | | | | |
| | surface- | | | | | |
| | treated | | | | | |
| | C = 12 silane | 27 | — | — | — | — |
| | agent | | | | | |
| | surface- | | | | | |
| | treated | | | | | |
| | C = 16 silane | — | 18 | — | — | — |
| | agent | | | | | |
| | surface- | | | | | |
| | treated | | | | | |

TABLE 4

| | | Comparative | Comparative | Comparative | Comparative |
|---|---|---|---|---|---|
| category | | Example 4 | Example 5 | Example 6 | Example 7 |
| epoxy- | biphenyl- | 3.200 | 3.200 | 3.200 | — |
| based | based | | | | |
| compound | compound | | | | |
| | (a) | | | | |
| | biphenyl- | 1.372 | 1.372 | 1.372 | 1.970 |
| | aralkyl- | | | | |
| | based | | | | |
| | compound | | | | |
| | (b) | | | | |
| | bisphenol | — | — | — | 4.578 |
| | F type (c) | | | | |
| curing agent | | 4.549 | 4.549 | 4.549 | 2.460 |
| curing catalyst | | 0.069 | 0.069 | 0.069 | 0.182 |
| coupling | amino | 0.270 | 0.270 | 0.270 | 0.270 |
| agent | silane- | | | | |
| | based | | | | |
| | epoxy | — | — | — | — |
| | silane- | | | | |
| | based | | | | |
| | acrylic | — | — | — | — |
| | silane- | | | | |
| | based | | | | |
| colorant | | 0.270 | 0.270 | 0.270 | 0.270 |
| release agent | | 0.270 | 0.270 | 0.270 | 0.270 |
| alumina | non-silane | 88 | 88 | 81 | 81 |
| | treated | | | | |
| | C = 6 silane | — | — | 9 | — |
| | agent | | | | |
| | surface- | | | | |
| | treated | | | | |
| | C = 8 silane | — | — | — | 9 |
| | agent | | | | |
| | surface- | | | | |
| | treated | | | | |
| | C = 12 silane | 2 | — | — | — |
| | agent | | | | |
| | surface- | | | | |
| | treated | | | | |
| | C = 16 silane | — | 2 | — | — |
| | agent | | | | |
| | surface- | | | | |
| | treated | | | | |

Specific compounds used in Tables 1 to 4 are as follows.
(1) Epoxy-based compound
(a) biphenyl-based compound (YX-4000H, Mitsubishi Chemical, Chemical Formula 1-1)

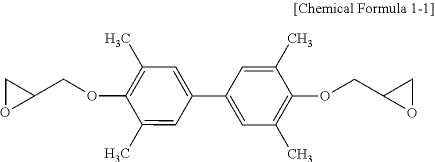 [SMILES: Cc1cc(-c2cc(C)c(OCC3CO3)c(C)c2)cc(C)c1OCC1CO1]

(b) biphenyl-aralkyl-based compound (NC3000, Nippon Kayaku, Chemical Formula 2-1 structure)

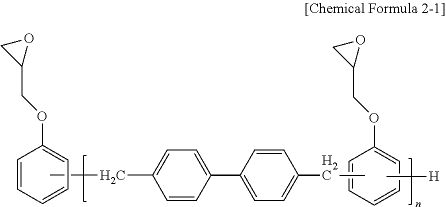

(c) bisphenol F type epoxy resin (YDF-2004, Kukdo Chemical)
(2) Curing agent: compound containing a unit of Chemical Formula 3 (MEH-7851SS, Meiwa)
(3) Curing catalyst: 2P4MZZ-PW, Shikoku
(4) Coupling agent
1) amino silane-based (Y9669, Momentive)
2) epoxy silane-based (KBM303, Shinetsu)
3) acrylic silane-based (KBM-5103, Shinetsu)
(5) Colorant: carbon black (MA-600, Mitsubishi Chemical)
(6) Alumina particles (product by Denka Korea)

### 1) Non-Silane Treated Alumina Particles (Second Alumina Particles)

A mixture of 72 wt % and 18 wt % of DAW03 (D50: 3 μm) and ASFP05S (D50: 0.5 μm), respectively, were used.

### 2) Silane Surface-Treated Alumina Particles (First Alumina Particles)

The mixture which is the same as that in non-silane treated alumina particles were surface-treated by silane agents below.
i) C=6 silane agent (compound of Chemical Formula 4-1 below)

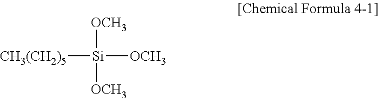

ii) C=8 silane agent (compound of Chemical Formula 4-2 below)

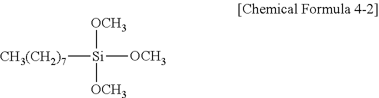

iii) C=12 silane agent (compound of Chemical Formula 4-3 below)

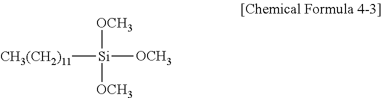

iv) C=16 silane agent (compound of Chemical Formula 4-4 below)

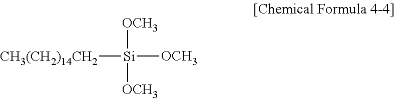

### Experimental Example

### (1) Measurement of Thermal Conductivity

After the resin compositions of Examples and Comparative Examples were completely cured at 175° C., a thermal conductivity of the cured resin composition was measured at 25° C. according to ASTM D5470 standard using a thermal conductivity measurement device (Laser Flash Technique (LFA)).

### (2) Measurement of Dielectric Constant

After the resin compositions of Examples and Comparative Examples were completely cured at 175° C., a dielectric constant of the cured product was measured at 1 MHz using a dielectric constant measurement device (Anritsu, product name MS46522B) under the conditions of temperature 25° C. and humidity 50%.

### (3) Evaluation of Spiral Flow

Using a spiral flow measurement mold manufactured based on a standard of EMMI-1-66, a flow length was evaluated for 120 seconds at a molding temperature of 175° C. and a molding pressure of 70 kgf/cm².

### (4) Measurement of Hardness

The resin compositions of Examples and Comparative Examples were cured at 175° C. for 90 seconds using an MPS (Multi Plunger System) molding apparatus, and then a hardness was measured using a Shore-D type hardness tester.

The measurement results are shown in Tables 5 to 7 below.

TABLE 5

| | Example | Example | Example | Example | Example | Example | Example | Example |
|---|---|---|---|---|---|---|---|---|
| | 1 | 2 | 3 | 4 | 5 | 6 | 7 | 8 |
| thermal | 3.38 | 3.51 | 3.41 | 3.57 | 3.66 | 3.48 | 3.63 | 3.15 |
| conductivity | | | | | | | | |
| (W/mK) | | | | | | | | |
| dielectric | 6.48 | 6.53 | 6.77 | 6.65 | 6.59 | 6.35 | 6.77 | 6.48 |
| constant | | | | | | | | |
| spiral flow | 57 | 60 | 66 | 57 | 62 | 70 | 68 | 73 |
| (flow | | | | | | | | |
| length) | | | | | | | | |
| (inch) | | | | | | | | |
| hardness | 76 | 77 | 73 | 78 | 85 | 75 | 88 | 76 |

TABLE 6

| | Example | Example | Example | Example | Example | Example | Example | Example |
|---|---|---|---|---|---|---|---|---|
| | 9 | 10 | 11 | 12 | 13 | 14 | 15 | 16 |
| thermal | 3.38 | 3.35 | 3.31 | 3.21 | 3.38 | 3.38 | 3.01 | 3.00 |
| conductivity | | | | | | | | |
| (W/mK) | | | | | | | | |
| dielectric | 6.48 | 6.55 | 6.76 | 6.48 | 6.48 | 6.48 | 6.78 | 6.8 |
| constant | | | | | | | | |
| spiral flow | 56 | 55 | 60 | 51 | 52 | 63 | 76 | 80 |
| (flow | | | | | | | | |
| length) | | | | | | | | |
| (inch) | | | | | | | | |
| hardness | 74 | 80 | 70 | 75 | 85 | 67 | 50 | 48 |

TABLE 7

| | Comparative | Comparative | Comparative | Comparative | Comparative | Comparative | Comparative |
|---|---|---|---|---|---|---|---|
| | Example 1 | Example 2 | Example 3 | Example 4 | Example 5 | Example 6 | Example 7 |
| thermal | 3.36 | 3.39 | 2.98 | 3.33 | 3.4 | 3.35 | 3.1 |
| conductivity | | | | | | | |
| (W/mK) | | | | | | | |
| dielectric | 6.67 | 6.7 | 6.57 | 6.57 | 6.65 | 6.54 | 6.87 |
| constant | | | | | | | |
| spiral flow | 48 | 47 | 73 | 48 | 49 | 50 | 43 |
| (flow | | | | | | | |
| length) | | | | | | | |
| (inch) | | | | | | | |
| hardness | 65 | 66 | 62 | 70 | 70 | 65 | 40 |

Referring to Tables 5 to 7, in Examples including the alumina particles treated with the silane agent having 7 or more carbon atoms in the alkyl group in a predetermined amount and including the biphenyl-based epoxy compound, the thermal conductivity, the flow length and the hardness were entirely improved, and low dielectric constants were provided.

In Comparative Examples 1, 2, 4 and 5 where the silane-treated alumina particles were not included or included in an excessively small amount, the flow length was significantly reduced. In Comparative Example 3 where the silane-treated alumina particles were included in an excessive amount, the thermal conductivity was reduced to less than 3.

In Comparative Example 6 where the alumina particles surface-treated with the silane agent having 8 carbon atoms in the alkyl group were used, the effect of increasing the flow length was not substantially implemented. In Comparative Example 7 where the bisphenol epoxy resin was used instead of the biphenyl-based compound, the flow length and hardness were significantly reduced.

In Example 12 where the acrylic silane-based compound was used as the silane coupling agent, the flow length was relatively reduced.

In Examples 15 and 16 where the content of the silane-treated alumina particles was slightly increased, the thermal conductivity was relatively lowered compared to those form other Examples.

1. A resin composition for sealing an electronic device, comprising:
an epoxy-based compound including a biphenyl-based epoxy compound; and
an inorganic filler including:
first alumina particles surface-treated with a silane agent, the silane agent including an alkyl group having 7 or more carbon atoms; and
second alumina particles that are not silane-treated,
wherein a content of the first alumina particles is in a range from 2.5 wt % to 35 wt % based on a total weight of the resin composition.

2. The resin composition according to claim 1, wherein the silane agent includes an alkyl group having 7 to 11 carbon atoms.

3. The resin composition according to claim 1, wherein the silane agent includes an alkyl group having 12 to 15 carbon atoms, and
the content of the first alumina particles is in a range from 2.5 wt % to 26 wt % based on the total weight of the resin composition.

4. The resin composition according to claim 1, wherein the silane agent includes an alkyl group having 16 to 20 carbon atoms, and
the content of the first alumina particles is in a range from 2.5 wt % to 17 wt % based on the total weight of the resin composition.

5. The resin composition according to claim 1, wherein a content of the second alumina particles is greater than the content of the first alumina particles.

6. The resin composition according to claim 1, wherein a content of the inorganic filler is in a range from 85 wt % to 95 wt % based on the total weight of the resin composition.

7. The resin composition according to claim 1, wherein a content of the biphenyl-based epoxy compound is in a range from 10 wt % to 80 wt % based on a total weight of the epoxy-based compound.

8. The resin composition according to claim 7, wherein the epoxy-based compound further includes a biphenyl-aralkyl-based epoxy compound.

9. The resin composition according to claim 8, wherein the biphenyl-based epoxy compound is represented by Chemical Formula 1 below: 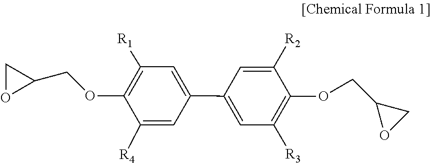
(wherein, in Chemical Formula 1, R₁, R₂, R₃ and R₄ are each independently hydrogen or an alkyl group having 1 to 5 carbon atoms.

10. The resin composition according to claim 8, wherein the biphenyl-aralkyl-based epoxy compound is represented by Chemical Formula 2 below: 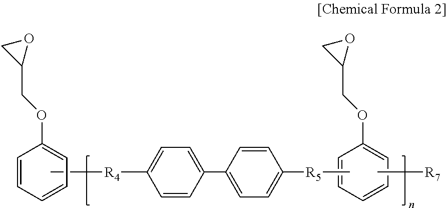
(wherein, in Chemical Formula 2, R₄ and R₅ are each an alkylene group having 1 to 5 carbon atoms, R₇ is hydrogen or an alkyl group having 1 to 5 carbon atoms, and n is an integer of 1 to 10).

11. The resin composition according to claim 1, further comprising a curing agent including a phenol-based or novolac-based resin, and a curing catalyst.

12. The resin composition according to claim 11, wherein a content of the curing catalyst is in a range from 0.01 to 0.5 wt % based on the total weight of the resin composition.

13. The resin composition according to claim 1, further comprising a silane coupling agent including an epoxy silane-based compound or an amino silane-based compound.

14. An electronic device comprising a sealant formed from the resin composition according to claim 1.

15. The electronic device according to claim 14, further comprising a circuit board and a semiconductor chip mounted on the circuit board,
wherein the sealant fills a space between the circuit board and the semiconductor chip.
